(19) United States
(12) Patent Application Publication
(10) Pub. No.: US 2025/0374495 A1
(43) Pub. Date: Dec. 4, 2025

(54) ELECTRONIC DEVICE

(71) Applicant: InnoLux Corporation, Miao-Li County (TW)

(72) Inventors: Sheng-Hui CHEN, Miao-Li County (TW); Shih-Siang YAN, Miao-Li County (TW); Po-Sheng CHENG, Miao-Li County (TW)

(21) Appl. No.: 19/191,236

(22) Filed: Apr. 28, 2025

(30) Foreign Application Priority Data
May 29, 2024 (CN) 202410676215.9

(51) Int. Cl. H05K 9/00; H01L 23/60

(52) U.S. Cl. CPC H05K 9/0054; H01L 23/60

(57) ABSTRACT

An electronic device is provided. The electronic device includes a substrate including a display area and a peripheral area surrounding the display area, and an electrostatic protection structure disposed in the peripheral area. The electrostatic protection structure includes a first metal layer, an insulating layer and a second metal layer. The first metal layer includes an adjacent first portion and a second portion. The insulating layer is disposed on the first metal layer. The second metal layer is disposed on the insulating layer and includes a third portion, a fourth portion and a connecting portion between the third portion and the fourth portion. In a schematic top view, the first portion overlaps the third portion. The second portion overlaps the fourth portion. The connecting portion does not overlap the first metal layer.

### CROSS REFERENCE TO RELATED APPLICATIONS

This application claims priority of China Patent Application No. 2024106762159, filed on May 29, 2024, the entirety of which is incorporated by reference herein.

### BACKGROUND

### Technical Field

The present disclosure relates to an electronic device, and in particular it relates to an electronic device with an electrostatic protection structure.

### Description of the Related Art

Generally speaking, an electrostatic protection structure is installed directly between two large metal patterns on the same layer to discharge electrostatic charges on the large patterns to avoid electrostatic discharge (ESD) caused by excessive voltage differences.

However, once electrostatic discharge (ESD) occurs, if the insulating layer located above the edges of adjacent lines in the electrostatic protection structure is broken, and an upper metal layer is subsequently deposited, the upper and lower metal layers may short-circuit, which in turn may cause adjacent lines to short-circuit and the panel to become disabled.

### SUMMARY

In accordance with one embodiment of the present disclosure, an electronic device is provided. The electronic device includes a substrate including a display area and a peripheral area surrounding the display area, and an electrostatic protection structure disposed in the peripheral area. The electrostatic protection structure includes a first metal layer, an insulating layer and a second metal layer. The first metal layer includes an adjacent first portion and a second portion. The insulating layer is disposed on the first metal layer. The second metal layer is disposed on the insulating layer and includes a third portion, a fourth portion and a connecting portion between the third portion and the fourth portion. In a schematic top view, the first portion overlaps the third portion. The second portion overlaps the fourth portion. The connecting portion does not overlap the first metal layer.

### BRIEF DESCRIPTION OF THE DRAWINGS

The disclosure can be more fully understood from the following detailed description when read with the accompanying figures. It is worth noting that in accordance with standard practice in the industry, various features are not drawn to scale. In fact, the dimensions of the various features may be arbitrarily increased or reduced for clarity of discussion.

FIG. 1 shows a schematic top view of an electronic device in accordance with one embodiment of the present disclosure;

FIG. 2A shows a schematic top view of an electrostatic protection structure in an electronic device in accordance with one embodiment of the present disclosure;

FIG. 2B shows a schematic cross-sectional view of an electrostatic protection structure in an electronic device in accordance with one embodiment of the present disclosure;

FIG. 3A shows a schematic top view of an electrostatic protection structure in an electronic device in accordance with one embodiment of the present disclosure;

FIG. 3B shows a schematic cross-sectional view of an electrostatic protection structure in an electronic device in accordance with one embodiment of the present disclosure;

FIG. 4A shows a schematic top view of an electrostatic protection structure in an electronic device in accordance with one embodiment of the present disclosure; and

FIG. 4B shows a schematic cross-sectional view of an electrostatic protection structure in an electronic device in accordance with one embodiment of the present disclosure.

### DETAILED DESCRIPTION

The following description lists various embodiments of this disclosure to introduce the basic concepts of this case, and is not intended to limit the content of this case. The actual scope of the invention should be defined according to the scope of the patent application. Reference will now be made in detail to exemplary embodiments of the present disclosure, examples of which are illustrated in the accompanying drawings. Whenever possible, the same reference numbers are used in the drawings and descriptions to refer to the same or similar parts.

Throughout this disclosure and the appended claims, certain words are used to refer to specific components. Those skilled in the art will appreciate that the device manufacturers may refer to the same components by different names. This article is not intended to differentiate between components that have the same functionality but different names. In the following description and claims, the words “comprise”, “include” and “contain” are open-ended words, and therefore they should be interpreted to mean “comprising but not limited to . . . ”.

The directional terms mentioned in this article, such as: “up”, “down”, “front”, “back”, “left”, “right”, etc., are only for reference to the directions of the accompanying drawings. The directional terms in this paper are used to define the relative positions of the illustrated components, and are not intended to limit the disclosure. In the drawings, each figure illustrates the general features of methods, structures, and/or materials used in particular embodiments. However, these drawings should not be interpreted as defining or limiting the scope or nature encompassed by these embodiments. For example, the relative sizes, thicknesses, and locations of the different layers, regions, and/or structures may be shrunken or enlarged for clarity.

In this paper, one structure (or layer, or component, or substrate) located on/above another structure (or layer, or component, or substrate) may mean that the two structures are directly connected, or the two structures are adjacent but not directly connected. Indirect connection means that there is at least one intermediary structure (or intermediary layer, intermediary component, intermediary substrate, intermediary spacer) between two structures. The lower surface of upper structure is adjacent to or directly connected to the upper surface of the intermediary structure. The upper surface of the lower structure is adjacent to or directly connected to the lower surface of the intermediate structure. The intermediary structure may be a single-layer/multi-layer physical structure, or a non-physical structure (there is no limit). In this disclosure, when a structure is disposed “on” another structure, it may mean that the structure is “directly” on the other structure, or that the structure is “indirectly” on the other structure (that is, between the two structures, at least one other structure is also sandwiched.

The terms “about”, “equal to”, “the same”, “substantially” or “roughly” are generally interpreted to mean an offset within 20% of a given value or range, or to mean an offset within 10%, 5%, 3%, 2%, 1% or 0.5% of a given value or range.

Furthermore, any two numerical values or directions used for comparison may have certain errors. If the first value is equal to the second value, it implies that there may be a tolerable error difference about 10%. If a first direction is perpendicular or approximately perpendicular to a second direction, the angle between the first direction and the second direction may be 80-100 degrees. If the first direction is parallel or substantially parallel to the second direction, the angle between the first direction and the second direction may be 0-10 degrees.

The ordinal numbers used in the description and claims, such as “first”, “second”, etc., are used for identification between components. They do not imply the existence of a component with the previous ordinal number. Such ordinal numbers do not represent the order of the components, or the order of manufacturing procedures. These ordinal numbers are used to clearly distinguish two components with the same naming. The ordinal numbers given to the components in the claims may be different from the ordinal numbers given to the components in the description. Accordingly, the first component in the description may be the second component in the claim.

In the disclosure, descriptions like “a given range is from a first value to a second value” or “a given range falls within the range between a first value and a second value” indicate that the given range includes the first value, the second value, and other values between them.

It should be understood that in the exemplary embodiments of the disclosure, the depth, thickness, width, or height of each component, or the spacing of, or distance between, components may be measured by an optical microscope (OM), a scanning electron microscope (SEM), a film thickness measurement device (α-step), or an ellipsometer. In some exemplary embodiments, a cross-sectional structural image of a component may be captured by a scanning electron microscope, which also measures the depth, thickness, width or height of each component, or the spacing of components or the distance between them.

An electronic device may include an imaging device, a laminated device, a display device, a backlight device, an antenna device, an assembled device, a touch display, a curved display, or a free shape display, but not limited thereto. The electronic device may use display media like liquid crystal, light-emitting diodes, fluorescence, phosphor, or any other suitable display media, or a combination of the above, but it is not limited thereto. A display device may be a non-self-luminous display device or a self-luminous display device. An antenna device may be a liquid-crystal type antenna device or a non-liquid-crystal type antenna device. A sensing device may use sensors sensing capacitance, light, heat energy or ultrasonic waves, but it is not limited thereto. An assembled device may be an assembled display device or an assembled antenna device, but it is not limited thereto. It should be noted that the electronic device can be any combination of the above, but it is not limited thereto. The electronic device may be a bendable or flexible electronic device. It should be noted that the electronic device can be any combination of the above, but it is not limited thereto. In addition, the shape of the electronic device may be a rectangular shape, a circular shape, a polygonal shape, a shape with curved edges, or other suitable shapes. The electronic device may have peripheral systems such as a driving system, a control system, a light source system, a structural system, etc., to form the display device, antenna device or assembled device.

It should be noted that in the embodiments shown below, features in several different embodiments may be replaced, reorganized, or combined without departing from the spirit of the present disclosure. Features in various embodiments may be combined as long as they do not violate the spirit of the disclosure or conflict with each other.

Unless otherwise defined, all terms (including technical and scientific terms) used herein have the same meaning as commonly understood by one of ordinary skill in the art. It is understood that these terms, such as those defined in commonly used dictionaries, should be interpreted to have a meaning consistent with the relevant technology and the background or context of the present disclosure, and should not be interpreted in an idealized or overly formal manner (unless otherwise defined).

In addition, the word “adjacent” in the description and claims, for example, is used to describe mutual proximity and does not necessarily mean that they are in contact with each other.

In addition, descriptions such as “when . . . ” or “at the moment” in this disclosure means a period of time, from prior to the event to later than the event. It is not limited to events happen just at the same time, which are announced in advance here. Furthermore, “disposed on” and other similar descriptions in this disclosure indicate the relative positions of objects, and do not limit to a physical contact between the objects, unless there are special limitations. Furthermore, when the present disclosure describe multiple functions, and the word “or” is used in listing the functions, it means that the functions can exist independently, but it does not exclude that multiple functions may exist at the same time.

In addition, words such as “electrically connected” or “coupled” in the description and claims not only refer to a direct electrical connection between the different objects, but also refer to an indirect electrical connection between the different objects. Electrical connection includes direct electrical connection, indirect electrical connection, or wireless communication between the different objects.

In this present disclosure, when “or” is used as a connective word between multiple elements, unless otherwise stated, the expressions of “and” and “or” are included.

In the present disclosure, when a certain element is disposed on another element, it means that the certain element may be disposed on a certain side of another element, such as but not limited to above, below, left, right, front, or back side. The two elements may not directly contact to each other.

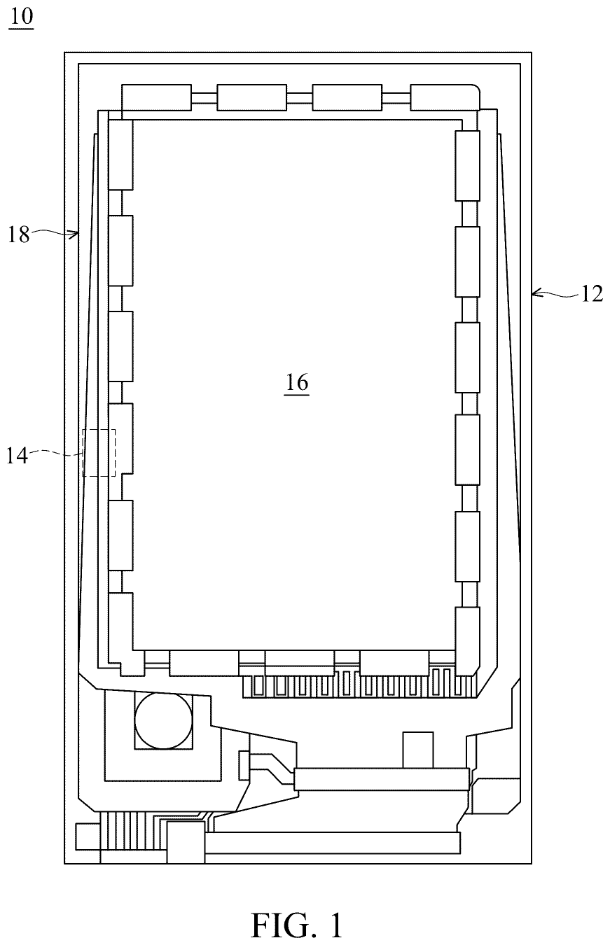

Referring to FIG. 1, in accordance with one embodiment of the present disclosure, an electronic device 10 is provided. FIG. 1 is a schematic top view of the electronic device 10.

As shown in FIG. 1, the electronic device 10 includes a substrate 12 and an electrostatic protection structure 14. The substrate 12 includes a display area 16 and a peripheral area 18. The peripheral area 18 surrounds the display area 16. In one embodiment, the electrostatic protection structure 14 is disposed in the peripheral area 18. The display area 16 can be defined as an area where an active-component array is disposed on the substrate 12 and is used as an area for displaying images. The peripheral area 18 can be defined as an area outside the display area 16 where no active-component array is provided, and is used to set peripheral circuits or driving circuits.

In accordance with some embodiments, the substrate 12 may include a hard substrate or a flexible substrate. In accordance with some embodiments, the hard substrate may include, for example, a silicon substrate, a glass substrate, a quartz substrate, a ceramic substrate, a metal substrate, a metal oxide substrate, or a combination thereof, but it is not limited thereto. In accordance with some embodiments, the flexible substrate may include, for example, a thinned glass substrate, a plastic substrate, a thinned metal substrate, or a combination thereof, but it is not limited thereto. In accordance with some embodiments, the plastic substrate may include, for example, polyethylene naphthalate (PEN), polyethylene terephthalate (PET), polyether sulfone (PES), polycarbonate (PC), polyacrylate (PA), polysiloxane, polynorbornene (PNB), polyetheretherketone (PEEK), polyetherimide (PEI), polyimide (PI), or a combination thereof, but it is not limited thereto.

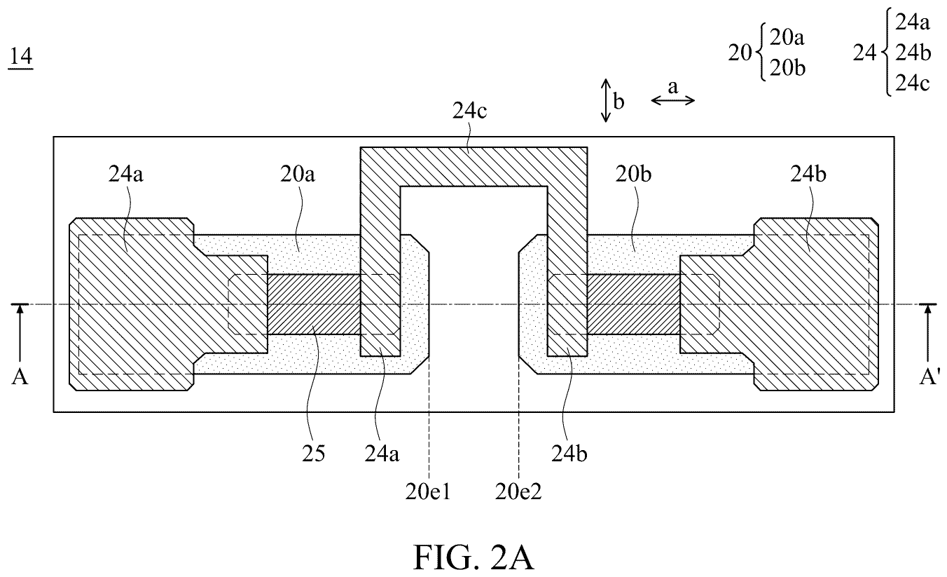

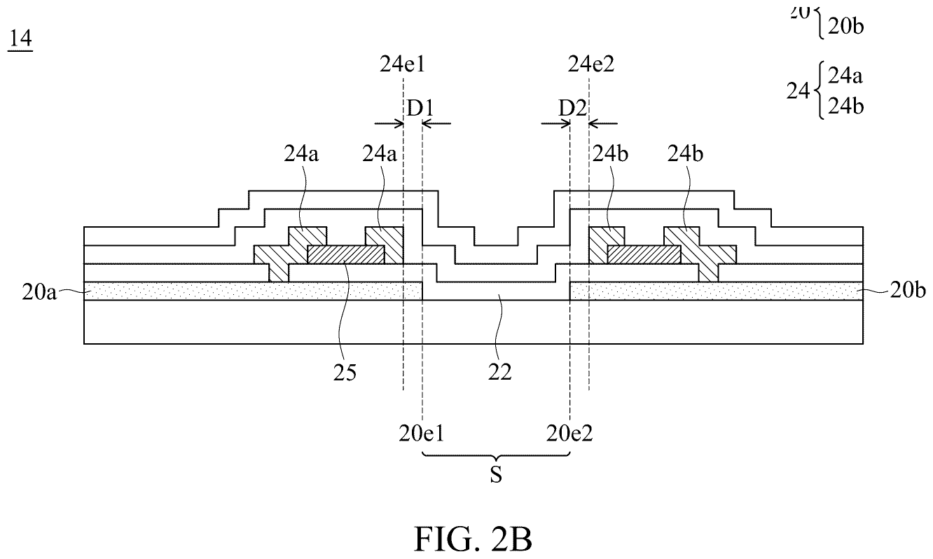

The electrostatic protection structure 14 in the electronic device 10 will be further described below with reference to FIGS. 2A and 2B. FIG. 2A is a schematic top view of the electrostatic protection structure 14. FIG. 2B is a schematic cross-sectional view taken along A-A′ cross-sectional line in FIG. 2A.

As shown in FIGS. 2A and 2B, the electrostatic protection structure 14 includes a first metal layer 20, an insulating layer 22 and a second metal layer 24. The first metal layer 20 includes an adjacent first portion 20a and a second portion 20b. The insulating layer 22 is disposed on the first metal layer 20. The second metal layer 24 is disposed on the insulating layer 22. The second metal layer 24 includes a third portion 24a, a fourth portion 24b and a connecting portion 24c, wherein the connecting portion 24c is between the third portion 24a and the fourth portion 24b. In the schematic top view shown in FIG. 2A, the first portion 20a of the first metal layer 20 overlaps the third portion 24a of the second metal layer 24. The second portion 20b of the first metal layer 20 overlaps the fourth portion 24b of the second metal layer 24. The connecting portion 24c of the second metal layer 24 does not overlap the first metal layer 20.

As shown in FIGS. 2A and 2B, in accordance with some embodiments, the third portion 24a of the second metal layer 24 may include two discontinuous metal layers, and the two metal layers are coupled through a semiconductor layer 25. In accordance with some embodiments, the fourth portion 24b of the second metal layer 24 may include two discontinuous metal layers, and the two metal layers are coupled through the semiconductor layer 25. The material of the semiconductor layer 25 may include, for example, amorphous silicon, polysilicon or metal oxide, but it is not limited thereto. The metal oxide may include indium gallium zinc oxide (IGZO), but it is not limited thereto.

In accordance with some embodiments, the first metal layer 20 and the second metal layer 24 may include, for example, copper (Cu), silver (Ag), gold (Au), molybdenum (Mo), tungsten (W), tantalum (Ta), aluminum (Al), or a combination thereof, but it is not limited thereto.

In accordance with some embodiments, the insulating layer 22 may include, for example, silicon oxide, silicon nitride, silicon oxynitride, or a combination thereof, but it is not limited thereto.

As shown in FIG. 2A, the connecting portion 24c extends in different directions from the third portion 24a of the second metal layer 24. For example, the connecting portion 24c extends in direction a and the third portion 24a extends in direction b, and direction a is different from direction b. In accordance with some embodiments, the third portion 24a, the fourth portion 24b, and the connecting portion 24c of the second metal layer 24 can be connected to form any shape, so as to avoid the edge 20e1 (where electrostatic discharge (ESD) is prone to occur) of the first portion 20a of the first metal layer 20 and the edge 20e2 (where electrostatic discharge (ESD) is prone to occur) of the second portion 20b of the first metal layer 20. In accordance with some embodiments, the third portion 24a, the fourth portion 24b, and the connecting portion 24c of the second metal layer 24 may be connected to form, for example, a U-shape, as shown in FIG. 2A, but it is not limited thereto. In accordance with some embodiments, the third portion 24a, the fourth portion 24b, and the connecting portion 24c of the second metal layer 24 may be connected to form, for example, an arc shape, but it is not limited thereto. In some embodiments, the first portion 20a and the second portion 20b of the first metal layer 20 have a distance in the extending direction of the connecting portion 24c, which means that they do not overlap in the extending direction of the connecting portion 24c. In other embodiments, the first portion 20a and the second portion 20b of the first metal layer 20 have a distance in the extending direction of the first portion 20a of the first metal layer 20, which means that they do not overlap in the extending direction of the first portion 20a of the first metal layer 20. This design can reduce the occurrence of electrostatic discharge (ESD) by increasing the spatial hindrance of electrostatic discharge.

As shown in the left half of FIG. 2B, the distance D1 in the horizontal direction between the edge 20e1 of the first portion 20a of the first metal layer 20 and the edge 24e1 of the third portion 24a of the second metal layer 24 may be, for example, greater than or equal to 1 μm and less than or equal to 150 μm, but it is not limited thereto. In accordance with some embodiments, the distance D1 in the horizontal direction between the edge 20e1 of the first portion 20a of the first metal layer 20 and the edge 24e1 of the third portion 24a of the second metal layer 24 may be, for example, greater than or equal to 2 μm and less than or equal to 100 μm. In another embodiment, the distance D1 in the horizontal direction between the edge 20e1 of the first portion 20a of the first metal layer 20 and the edge 24e1 of the third portion 24a of the second metal layer 24 may be, for example, greater than or equal to 4 μm and less than or equal to 50 μm, but it is not limited thereto. At an appropriate distance D1, the electrostatic protection structure 14 has better anti-static effect and space utilization.

As shown in the right half of FIG. 2B, the distance D2 in the horizontal direction between the edge 20e2 of the second portion 20b of the first metal layer 20 and the edge 24e2 of the fourth portion 24b of the second metal layer 24 may be, for example, greater than or equal to 1 μm and less than or equal to 150 μm, but it is not limited thereto. In accordance with some embodiments, the distance D2 in the horizontal direction between the edge 20e2 of the second portion 20b of the first metal layer 20 and the edge 24e2 of the fourth portion 24b of the second metal layer 24 may be, for example, greater than or equal to 2 μm and less than or equal to 100 μm, but it is not limited thereto. In accordance with some embodiments, the distance D2 in the horizontal direction between the edge 20e2 of the second portion 20b of the first metal layer 20 and the edge 24e2 of the fourth portion 24b of the second metal layer 24 may be, for example, greater than or equal to 4 μm and less than or equal to 50 μm. At an appropriate distance D2, the electrostatic protection structure 14 has better anti-static effect and space utilization.

In accordance with some embodiments, the first metal layer 20 may further extend to the display area 16. In some embodiments, the first metal layer 20 extends to the display area 16 to serve as other functional components in the display area 16, such as gates in transistors, but it is not limited thereto.

As shown in FIG. 2B, there is a spacing S between the first portion 20a and the second portion 20b of the first metal layer 20. In accordance with some embodiments, the spacing S between the first portion 20a and the second portion 20b of the first metal layer 20 may be, for example, greater than or equal to 1 μm and less than or equal to 200 μm, but it is not limited thereto. In accordance with some embodiments, the spacing S between the first portion 20a and the second portion 20b of the first metal layer 20 may be, for example, greater than or equal to 5 μm and less than or equal to 20 μm, but it is not limited thereto. At an appropriate spacing S, the electrostatic protection structure 14 has better anti-static effect and space utilization.

When electrostatic discharge (ESD) occurs, if the insulating layer 22 located above the edges of the first portion 20a (for example, a second line) and the second portion 20b (for example, a first line) of the first metal layer 20 in the electrostatic protection structure 14 is broken, and the second metal layer 24 is subsequently deposited, the first metal layer 20 and the second metal layer 24 will be short-circuited, thereby causing a short-circuit in a wide range of lines (for example, the first line and the second line), and causing the panel to become disabled. In the embodiment shown in FIGS. 2A and 2B, the second metal layer 24 of the electrostatic protection structure 14 is bypassed at points prone to electrostatic discharge (ESD) so that the second metal layer 24 does not overlap with the edge of the first metal layer 20, which can prevent the first metal layer 20 and the second metal layer 24 from short-circuiting after the insulating layer 22 is damaged by electrostatic discharge (ESD), effectively increasing the survival rate of the electrostatic protection structure 14 and the panel (circuit) after the occurrence of electrostatic discharge (ESD).

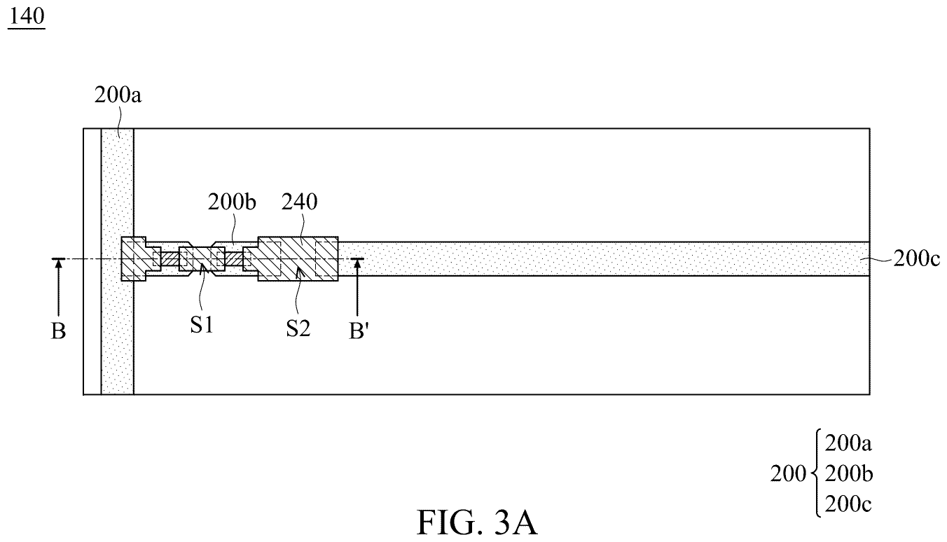

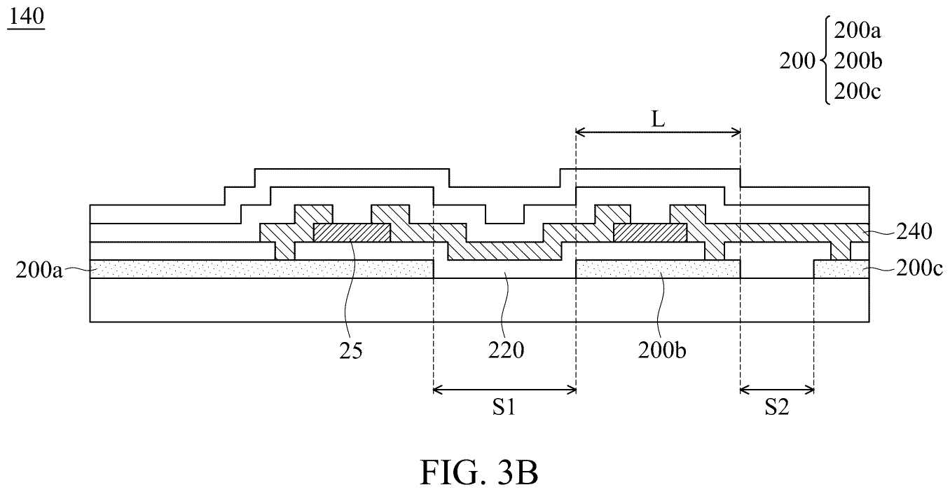

Another electrostatic protection structure 140 in the present electronic device will be further described below with reference to FIGS. 3A and 3B. FIG. 3A is a schematic top view of the electrostatic protection structure 140. FIG. 3B is a schematic cross-sectional view taken along B-B′ cross-sectional line in FIG. 3A.

As shown in FIGS. 3A and 3B, the electrostatic protection structure 140 includes a first metal layer 200, an insulating layer 220, and a second metal layer 240. The first metal layer 200 includes, for example, a first portion 200a, a second portion 200b, and a third portion 200c. For example, the first portion 200a is adjacent to the second portion 200b, and the second portion 200b is adjacent to the third portion 200c. The insulating layer 220 is disposed on the first metal layer 200. The second metal layer 240 is disposed on the insulating layer 220.

As shown in FIGS. 3A and 3B, in accordance with some embodiments, the second metal layer 240 may include two discontinuous metal layers, and the two metal layers are coupled through the semiconductor layer 25. The material of the semiconductor layer 25 may include, for example, amorphous silicon, polysilicon or metal oxide, but it is not limited thereto. The metal oxide may include indium gallium zinc oxide (IGZO), but it is not limited thereto.

In accordance with some embodiments, the first metal layer 200 and the second metal layer 240 may include, for example, copper (Cu), silver (Ag), gold (Au), molybdenum (Mo), tungsten (W), tantalum (Ta), aluminum (Al), or a combination thereof, but it is not limited thereto.

In accordance with some embodiments, the insulating layer 220 may include, for example, silicon oxide, silicon nitride, silicon oxynitride, or a combination thereof, but it is not limited thereto.

In accordance with some embodiments, the first metal layer 200 may further extend to the display area 16 as shown in FIG. 1.

As shown in FIGS. 3A and 3B, there is a spacing S1 between the first portion 200a and the second portion 200b of the first metal layer 200. In accordance with some embodiments, the spacing S1 between the first portion 200a and the second portion 200b of the first metal layer 200 may be, for example, greater than or equal to 1 μm and less than or equal to 500 μm, but it is not limited thereto. In accordance with some embodiments, the spacing S1 between the first portion 200a and the second portion 200b of the first metal layer 200 may be, for example, greater than or equal to 5 μm and less than or equal to 20 μm, but it is not limited thereto. At an appropriate spacing S1, the electrostatic protection structure 140 has better anti-static effect and space utilization. There is a spacing S2 between the second portion 200b and the third portion 200c of the first metal layer 200. In accordance with some embodiments, the spacing S2 between the second portion 200b and the third portion 200c of the first metal layer 200 may be, for example, greater than or equal to 1 μm and less than or equal to 500 μm, but it is not limited thereto. In accordance with some embodiments, the spacing S2 between the second portion 200b and the third portion 200c of the first metal layer 200 may be, for example, greater than or equal to 5 μm and less than or equal to 20 μm, but it is not limited thereto. At an appropriate spacing S2, the electrostatic protection structure 140 has better anti-static effect and space utilization.

As shown in FIG. 3B, in the first metal layer 200, the second portion 200b is separated from the first portion 200a on one side of the second portion 200b by the spacing S1, and is separated from the third portion 200c on the other side of the second portion 200b by the spacing S2. In accordance with some embodiments, the length L of the second portion 200b between the spacing S1 and the spacing S2 may be, for example, greater than or equal to 10 μm and less than or equal to 100 μm, but it is not limited thereto. At an appropriate length L, the electrostatic protection structure 14 has better anti-static effect and space utilization.

In accordance with some embodiments, as shown in FIG. 3B, the first metal layer 200 may include a single floating metal layer. For example, the first metal layer 200 includes a first portion 200a, a second portion 200b, and a third portion 200c. The second portion 200b is located between the first portion 200a and the third portion 200c, and there is a gap on both sides of the second portion 200b (for example, the spacing S1 and S2). In the embodiment shown in FIG. 3B, the second portion 200b may be called a floating metal layer, but the number of floating metal layers is not limited thereto, and other appropriate numbers of floating metal layers are also applicable to the present disclosure. In accordance with some embodiments, the first metal layer 200 may include two floating metal layers (not shown). For example, the first metal layer 200 includes a first portion, a second portion, a third portion, and a fourth portion. The second portion is adjacent to the third portion, and the second portion and the third portion are between the first portion and the fourth portion. There are gaps on both sides of the second portion and the third portion respectively. At this time, the second portion and the third portion can be called floating metal layers, but the number of floating metal layers is not limited thereto, and other appropriate numbers of floating metal layers are also applicable to the present disclosure.

During the process of manufacturing the electrostatic protection structure 140, it is considered that large voltage differences are likely to occur between large patterns on the same layer. Therefore, multiple gaps are designed to be formed in the first metal layer 200 (for example, through the spacing S1 and S2, the floating second portion 200b is formed between the first portion 200a (e.g., a second line) and the third portion 200c (e.g., a first line) of the first metal layer 200). The energy barrier (formed by the spacing S2) for the electrostatic charges accumulated on the third portion 200c (e.g., the first line) to jump to the second portion 200b in the first metal layer 200 is increased. Also, the energy barrier (formed by the spacing S1) for the electrostatic charges on the second portion 200b to jump to the first portion 200a (e.g., the second line) is increased, such that electrostatic discharge (ESD) is less likely to be induced between the first line and the second line. That is, by increasing the spatial hindrance (i.e. forming at least one floating metal layer (e.g., the second portion 200b) with gaps on both sides between the first line and the second line) of electrostatic discharge, electrostatic discharge (ESD) can be less likely to occur even if a voltage difference occurs between large patterns during the production of electrostatic protection structures. The spacing between any two adjacent portions of the first metal layer may be the same or different, but it is not limited thereto.

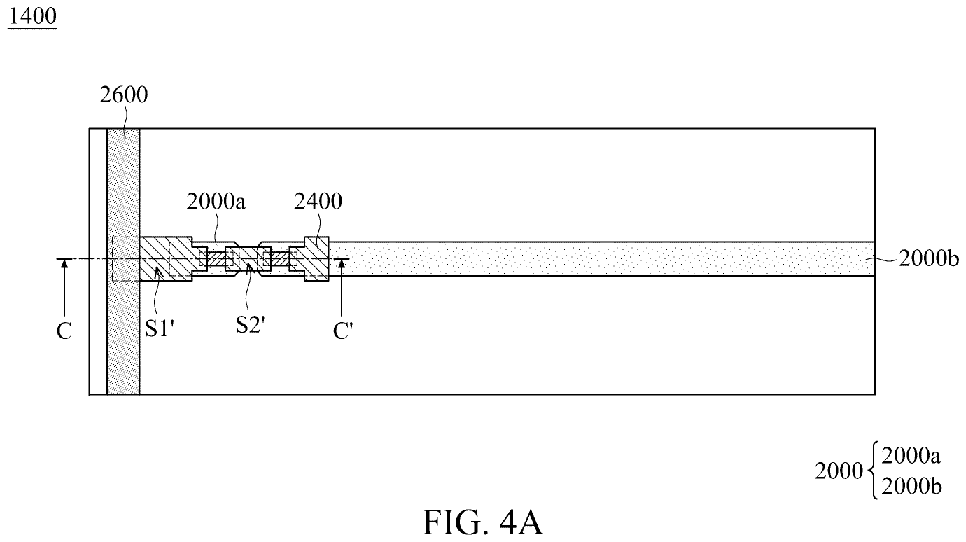

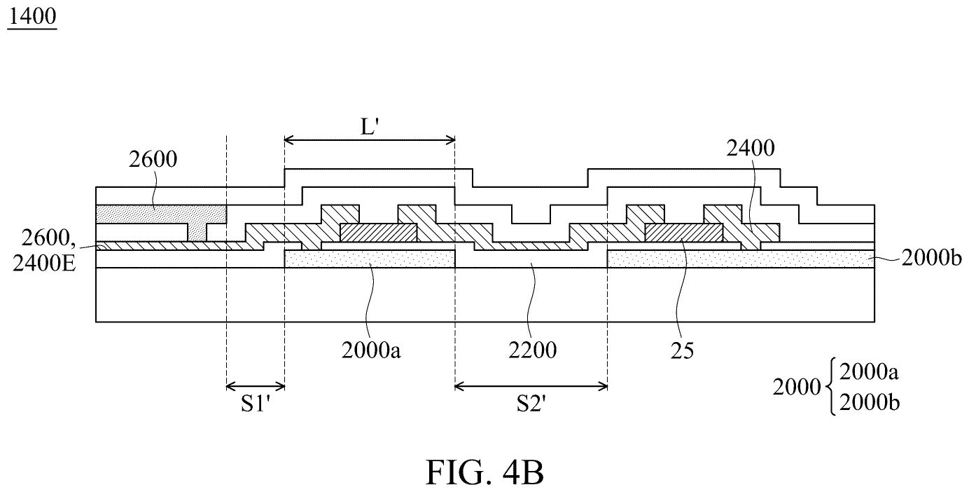

Another electrostatic protection structure 1400 in the present electronic device will be further described below with reference to FIGS. 4A and 4B. FIG. 4A is a schematic top view of the electrostatic protection structure 1400. FIG. 4B is a schematic cross-sectional view taken along C-C′ cross-sectional line in FIG. 4A.

As shown in FIGS. 4A and 4B, the electrostatic protection structure 1400 includes a first metal layer 2000, an insulating layer 2200, a second metal layer 2400, and a conductive layer 2600. The first metal layer 2000 includes, for example, a first portion 2000a and a second portion 2000b. The insulating layer 2200 is disposed on the first metal layer 2000. The second metal layer 2400 is disposed on the insulating layer 2200. The conductive layer 2600 is disposed on the insulating layer 2200 and is electrically connected to the first metal layer 2000. It should be noted that the conductive layer 2600 and the first metal layer 2000 are located on different layers. In accordance with some embodiments, the conductive layer 2600 (e.g., the third metal layer) may be disposed on the second metal layer 2400, as shown in FIG. 4B, but it is not limited thereto.

As shown in FIGS. 4A and 4B, in accordance with some embodiments, the second metal layer 2400 may include two discontinuous metal layers, and the two metal layers are coupled through the semiconductor layer 25. The material of the semiconductor layer 25 includes, for example, amorphous silicon, polysilicon or metal oxide, but it is not limited thereto. The metal oxide may include indium gallium zinc oxide (IGZO), but it is not limited thereto.

In accordance with some embodiments, the first metal layer 2000, the second metal layer 2400, and the conductive layer 2600 may include, for example, copper (Cu), silver (Ag), gold (Au), molybdenum (Mo), tungsten (W), tantalum (Ta), aluminum (Al), or a combination thereof, but are not limited thereto.

In accordance with some embodiments, the insulating layer 2200 may include, for example, silicon oxide, silicon nitride, silicon oxynitride, or a combination thereof, but it is not limited thereto.

In accordance with some embodiments, the first metal layer 2000 may further extend to the display area 16 as shown in FIG. 1.

As shown in FIGS. 4A and 4B, the first portion 2000a of the first metal layer 2000 and the conductive layer 2600 located on different layers are separated by a spacing S1′ in the horizontal direction. In accordance with some embodiments, the spacing S1′ in the horizontal direction between the first portion 2000a of the first metal layer 2000 and the conductive layer 2600 located on different layers may be, for example, greater than or equal to 1 μm and less than or equal to 30 μm, but it is not limited thereto. In accordance with some embodiments, the spacing S1′ in the horizontal direction between the first portion 2000a of the first metal layer 2000 and the conductive layer 2600 located on different layers may be, for example, greater than or equal to 5 μm and less than or equal to 20 μm, but it is not limited thereto. At an appropriate spacing S1′, the electrostatic protection structure 1400 has better anti-static effect and space utilization. The first portion 2000a and the second portion 2000b of the first metal layer 2000 are spaced apart by a spacing S2′. In accordance with some embodiments, the spacing S2′ between the first portion 2000a and the second portion 2000b of the first metal layer 2000 may be, for example, greater than or equal to 1 μm and less than or equal to 30 μm, but it is not limited thereto. In accordance with some embodiments, the spacing S2′ between the first portion 2000a and the second portion 2000b of the first metal layer 2000 may be, for example, greater than or equal to 5 μm and less than or equal to 20 μm, but it is not limited thereto. At an appropriate spacing S2′, the electrostatic protection structure 1400 has better anti-static effect and space utilization.

As shown in FIG. 4B, in the first metal layer 2000, the first portion 2000a is separated from the conductive layer 2600 by the spacing S1′ in the horizontal direction, and is separated from the second portion 2000b by the spacing S2′. The conductive layer 2600 is located on one side of the first portion 2000a. The conductive layer 2600 and the first portion 2000a are located on different layers. The second portion 2000b is located on the other side of the first portion 2000a. In accordance with some embodiments, the length L′ of the first portion 2000a between the spacing S1′ and the spacing S2′ may be, for example, greater than or equal to 10 μm and less than or equal to 40 μm, but it is not limited thereto. At an appropriate length L′, the electrostatic protection structure 1400 has better anti-static effect and space utilization.

In accordance with some embodiments, as shown in FIG. 4B, the first metal layer 2000 may include a single floating metal layer. For example, the first metal layer 2000 may include a first portion 2000a and a second portion 2000b. The first portion 2000a is located between the conductive layer 2600 and the second portion 2000b. The first portion 2000a and the conductive layer 2600 are located on different layers. There are gaps (for example, the spacing S1′ and S2′) on both sides of the first portion 2000a. In the embodiment shown in FIG. 4B, the first portion 2000a may be called a floating metal layer, but the number of floating metal layers is not limited thereto, and other appropriate numbers of floating metal layers are also applicable to the present disclosure. In accordance with some embodiments, the first metal layer 2000 may include two floating metal layers (not shown). For example, the first metal layer 2000 includes a first portion, a second portion, and a third portion. The first portion is adjacent to the second portion. The first portion and the second portion are located between the conductive layer and the third portion. The conductive layer is on a different layer than the first portion, the second portion, and the third portion. There are gaps on both sides of the first portion and the second portion respectively. At this time, the first portion and the second portion may be called floating metal layers, but the number of floating metal layers is not limited thereto, and other appropriate numbers of floating metal layers are also applicable to the present disclosure.

In accordance with some embodiments, the conductive layer 2600 may include an extending portion 2400E of the second metal layer 2400, as shown in FIG. 4B, but it is not limited thereto. In accordance with some embodiments, the conductive layer 2600 may include an ITO layer (not shown), but it is not limited thereto.

During the process of manufacturing the electrostatic protection structure 1400, it is considered that large voltage differences are likely to occur between large patterns on the same layer. Therefore, multiple gaps (for example, with the spacing S1′ and S2′, the first portion 2000a of the first metal layer 2000 forms a floating metal layer) are designed to be formed in the first metal layer 2000. The energy barrier (formed by the spacing S2′) for the electrostatic charges accumulated on the second portion 2000b (e.g., the first line) in the first metal layer 2000 to jump to the first portion 2000a is increased. At the same time, no adjacent large patterns of the same layer are provided on the side of the first portion 2000a of the first metal layer 2000 relative to the second portion 2000b, so that the electrostatic charges on the first portion 2000a cannot undergo the next transition. In the embodiment shown in FIGS. 4A and 4B, the large pattern of the same layer as shown in FIG. 3B is replaced with the conductive layer 2600 (e.g., the third metal layer) located at different layers from the first metal layer 2000, or the extending portion 2400E of the second metal layer 2400, or an ITO layer (not shown), or other metal layers (not shown) located at different layers from the first metal layer 2000 as the second line, so that electrostatic discharge (ESD) is not easily induced between the first line and the second line. That is, by increasing the spatial hindrance (i.e. forming at least one floating metal layer (e.g., the first portion 2000a) with gaps on both sides between the first line and the second line) of electrostatic discharge and replacing large patterns of the same layer with metal conductive layers located at different layers as the second line, in the process of manufacturing the electrostatic protection structure, electrostatic discharge (ESD) is less likely to occur even if there is a voltage difference between the patterns.

Although some embodiments of the present disclosure and their advantages have been described in detail, it should be understood that various changes, substitutions and alterations can be made herein without departing from the spirit and scope of the disclosure as defined by the appended claims. The features of the various embodiments can be used in any combination as long as they do not depart from the spirit and scope of the present disclosure. Moreover, the scope of the present application is not intended to be limited to the particular embodiments of the process, machine, manufacture, composition of matter, means, methods and steps described in the specification. As one of ordinary skill in the art will readily appreciate from the present disclosure, processes, machines, manufacture, compositions of matter, means, methods, or steps, presently existing or later to be developed, that perform substantially the same function or achieve substantially the same result as the corresponding embodiments described herein may be utilized according to the present disclosure. Accordingly, the appended claims are intended to include within their scope such processes, machines, manufacture, compositions of matter, means, methods or steps. In addition, each claim constitutes an individual embodiment, and the claimed scope of the present disclosure includes the combinations of the claims and embodiments. The scope of protection of present disclosure is subject to the definition of the scope of the appended claims. Any embodiment or claim of the present disclosure does not need to meet all the purposes, advantages, and features disclosed in the present disclosure.

What is claimed is:

1. An electronic device, comprising:
a substrate comprising a display area and a peripheral area surrounding the display area; and
an electrostatic protection structure disposed in the peripheral area, comprising:
a first metal layer comprising an adjacent first portion and a second portion;
an insulating layer disposed on the first metal layer; and
a second metal layer disposed on the insulating layer and comprising a third portion, a fourth portion and a connecting portion between the third portion and the fourth portion;
wherein, in a schematic top view, the first portion overlaps the third portion, the second portion overlaps the fourth portion, and the connecting portion does not overlap the first metal layer.

2. The electronic device as claimed in claim 1, wherein the third portion of the second metal layer comprises two discontinuous metal layers, and the two metal layers are coupled through a semiconductor layer.

3. The electronic device as claimed in claim 1, wherein the fourth portion of the second metal layer comprises two discontinuous metal layers, and the two metal layers are coupled through a semiconductor layer.

4. The electronic device as claimed in claim 1, wherein the connecting portion has an extending direction different from that of the third portion of the second metal layer.

5. The electronic device as claimed in claim 1, wherein the third portion, the fourth portion, and the connecting portion of the second metal layer are connected to form a U-shape.

6. The electronic device as claimed in claim 1, wherein the third portion, the fourth portion, and the connecting portion of the second metal layer are connected to form an arc shape.

7. The electronic device as claimed in claim 1, wherein the first portion and the second portion of the first metal layer do not overlap in an extending direction of the connecting portion.

8. The electronic device as claimed in claim 1, wherein the first portion and the second portion of the first metal layer do not overlap in an extending direction of the first portion of the first metal layer.

9. The electronic device as claimed in claim 1, wherein a distance in a horizontal direction between an edge of the first portion of the first metal layer and an edge of the third portion of the second metal layer is greater than or equal to 1 μm and less than or equal to 150 μm.

10. The electronic device as claimed in claim 1, wherein a distance in a horizontal direction between an edge of the second portion of the first metal layer and an edge of the fourth portion of the second metal layer is greater than or equal to 1 μm and less than or equal to 150 μm.

11. The electronic device as claimed in claim 1, wherein the first metal layer extends to the display area.

12. The electronic device as claimed in claim 1, wherein there is a spacing between the first portion and the second portion of the first metal layer.

13. The electronic device as claimed in claim 12, wherein the spacing is greater than or equal to 1 μm and less than or equal to 200 μm.

14. The electronic device as claimed in claim 12, wherein the first metal layer further comprises a third portion, and any two adjacent portions of the first metal layer are separated by the spacing.

15. The electronic device as claimed in claim 14, wherein there is a first spacing between the second portion and the first portion, there is a second spacing between the second portion and the third portion, and the second portion has a length greater than or equal to 10 μm and less than or equal to 100 μm.

16. The electronic device as claimed in claim 1, further comprising a conductive layer disposed on the insulating layer and electrically connected to the first metal layer.

17. The electronic device as claimed in claim 16, wherein a spacing in a horizontal direction between the first portion of the first metal layer and the conductive layer is greater than or equal to 1 μm and less than or equal to 30 μm.

18. The electronic device as claimed in claim 16, wherein the conductive layer is disposed on the second metal layer.

19. The electronic device as claimed in claim 16, wherein the conductive layer comprises an extending portion of the second metal layer.

20. The electronic device as claimed in claim 16, wherein the conductive layer comprises an ITO layer.
